(19) United States
(12) Patent Application Publication
(10) Pub. No.: US 2026/0314322 A1
(43) Pub. Date: Oct. 8, 2026

(54) METHOD FOR PRODUCING SEMICONDUCTOR DEVICE AND LAYERED OBJECT FOR SEMICONDUCTOR DEVICE

(71) Applicant: MITSUI CHEMICALS, INC., Chuo-ku, Tokyo (JP)

(72) Inventors: Rikuo KAJIWARA, Ichihara-shi, Chiba (JP); Ko TAKASE, Funabashi-shi, Chiba (JP); Masaki OKAZAKI, Chiba-shi, Chiba (JP)

(73) Assignee: MITSUI CHEMICALS, INC., Chuo-ku, Tokyo (JP)

(21) Appl. No.: 19/472,628

(22) PCT Filed: Apr. 1, 2024
(86) PCT No.: PCT/JP2024/013513

§ 371 Date: Oct. 3, 2025

(30) Foreign Application Priority Data
Apr. 5, 2023 (JP) 2023-061636

(51) Int. Cl. H10P 72/70; H10P 50/00; H10P 52/00

(52) U.S. Cl. CPC H10P 72/7416; H10P 52/00; H10P 72/7424; H10P 72/7442; H10P 50/692

(57) ABSTRACT

This method for producing a semiconductor device includes: a step in which a resin layer comprising a predetermined polyimide resin is formed on a substrate; a step in which a supporting substrate is bonded to the resin layer; a step in which the surface, on the reverse side from the resin layer, of the substrate having the supporting substrate bonded thereto is ground until the thickness becomes 150 μm or less; and a step in which the supporting substrate is removed. The resin layer satisfies relationship (1): −0.042*X+5.219*Y+0.144*Z−4.434≤31 (where X is the CTE of the resin layer, Y is the 23° C. tensile modulus of the resin layer, and Z is the Tg of the resin layer).

### TECHNICAL FIELD

The present invention relates to a method for producing a semiconductor device and a laminate for a semiconductor device.

### BACKGROUND ART

In a producing step of a semiconductor device, importance of processing of reducing the thickness of a semiconductor wafer (hereinafter, also referred to as “thinning processing”) has been increasing in recent years. The thinning processing is effective from the viewpoint of improving conduction performance represented by on-state characteristics in a field of a vertical power type semiconductor device such as a power device. This is because a current path in the semiconductor device is shortened by reducing the thickness of the semiconductor wafer.

The thinning processing is also referred to as a back-grinding step. In the back-grinding step of the semiconductor wafer, generally, the back surface of a semiconductor wafer is ground while the front surface of the semiconductor wafer is protected by a back-grinding tape. As such a back-grinding tape, for example, a tape including a base material and a pressure sensitive adhesive layer including a cured substance of a pressure sensitive adhesive composition is known (see PTL 1).

### CITATION LIST

### Patent Literature

### PTL 1

Japanese Patent Application Laid-Open No. 2022-024736

### SUMMARY OF INVENTION

### Technical Problem

However, the above-described back-grinding tape does not have sufficient rigidity to support a semiconductor wafer subjected to thinning processing to have a thickness of 150 μm or less. Therefore, the thinned semiconductor wafer is more likely to be bent, and damage or the like may occur during transportation. In addition, even after the thinning processing, a high-temperature process of processing the back surface of the semiconductor wafer at a high temperature may be performed, but the back-grinding tape does not have sufficient heat resistance to withstand the high-temperature process.

On the other hand, in order to support a semiconductor wafer having been subjected to thinning processing and to cope with a high process temperature, a method of adhering a support board (for example, a glass board) having high rigidity to the surface of the semiconductor wafer through a temporary fixing agent instead of the back-grinding tape has been investigated. As the temporary fixing agent, a resin layer having high heat resistance has been investigated in order to cope with the high-temperature process.

When the temporary fixing agent is applied to the surface of a semiconductor wafer and then heated, or when a heated resin film is transferred to form a resin layer and then cooled or the temporary fixing agent is heated in a back surface grinding step such as a adhering process or bump formation process and then cooled to room temperature, the semiconductor wafer to which the temporary fixing agent is applied is prone to bending. In addition, when the support board is peeled off after the back surface of the semiconductor wafer is ground, the semiconductor wafer to which the temporary fixing agent is applied is prone to bending, which may result in damage. In recent years, further thinning of the semiconductor wafer has progressed, and it is desired to further suppress the damage caused by the bending of the semiconductor wafer.

The present invention has been made in view of the above-described problems, and an object of the present invention is to provide a method for producing a semiconductor device and a laminate for a semiconductor device, each capable of reducing the bending of a semiconductor wafer, on which a temporary fixing agent is applied, in a producing step of a semiconductor device.

### Solution to Problem

[1] A method for producing a semiconductor device, the method including:
forming, on a board, a resin layer that includes a polyimide resin;
adhering a support board on the resin layer;
grinding a surface of the board until a thickness of the board becomes 150 μm or less, the board being a board to which the support board is adhered, the surface being located opposite to the resin layer; and
peeling off the support board,
in which
the resin layer satisfies equation (1) below:

W=−0.042*X+5.219*Y+0.144*Z−4.434≤31 equation (1):
(in the equation (1), X represents a linear thermal expansion coefficient (CTE) (ppm/K) of the resin layer, Y represents a tensile modulus (GPa) of the resin layer at 23° C., and Z represents a glass transition temperature (° C.) of the resin layer),
the polyimide resin includes a polycondensation unit of a tetracarboxylic acid dianhydride and a diamine, and a monomer composed of the tetracarboxylic acid dianhydride and the diamine includes a monomer (A) having an aliphatic chain, the monomer (A) including at least one of a tetracarboxylic acid dianhydride represented by formula (A1), a diamine represented by formula (A2), and a diamine represented by formula (A3), and a monomer (B) having an aromatic ring, the monomer (B) not corresponding to any of the tetracarboxylic acid dianhydride represented by the formula (A1), the diamine represented by the formula (A2), and the diamine represented by the formula (A3):

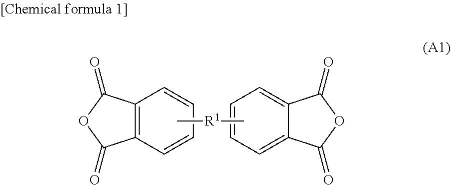

(R¹ in the formula (A1) represents an aliphatic chain having a main chain including at least one atom of C, N, and O, and a total number of atoms constituting the main chain is 4 to 20), and

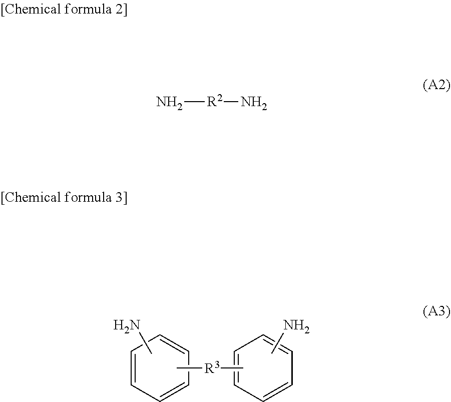

(R² in the formula (A2) and R³ in the formula (A3) each represent an aliphatic chain having a main chain including at least one atom of C, N, and O, and a total number of atoms constituting the main chain is 3 to 500).

[2] The method according to [1], in which the CTE of the resin layer is 40 ppm/K or more.

[3] The method according to [1] or [2], in which the tensile modulus of the resin layer is 0.5 to 30 GPa.

[4] The method according to any one of [1] to [3], in which the glass transition temperature Tg of the resin layer is 250° C. or lower.

[5] The method according to any one of [1] to [4], in which a thickness of the resin layer is 10 μm or more.

[6] The method according to any one of [1] to [5], in which the monomer includes 7 to 60 mol % of the monomer (A) and 40 to 93 mol % of the monomer (B) based on a total amount of the monomer.

[7] The method according to any one of [1] to [6], in which the monomer (B) includes an aromatic tetracarboxylic acid dianhydride represented by formula (B1):

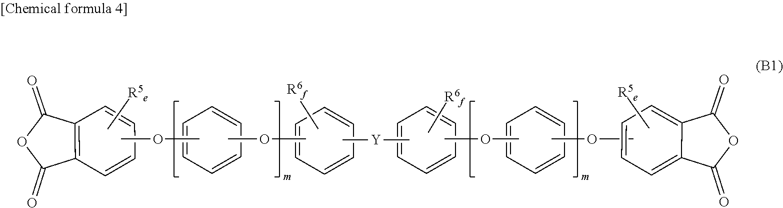

(in the formula (B1),
   Y represents a divalent group selected from the group consisting of an oxygen atom, a methylene group, and —CR^{a}R^{b} (R^{a} and R^{b} each represent a substituted or unsubstituted alkyl group having 1 to 3 carbon atoms),
   each m represents an integer of 0 or 1,
   R⁵ and R⁶ each represent a substituted or unsubstituted alkyl group having 1 to 3 carbon atoms or an alkoxy group having 1 to 3 carbon atoms, and
   e and f each represent an integer of 0 to 3).

[8] The method according to any one of [1] to [7], in which the monomer (B) includes an aromatic diamine represented by formula (B2),

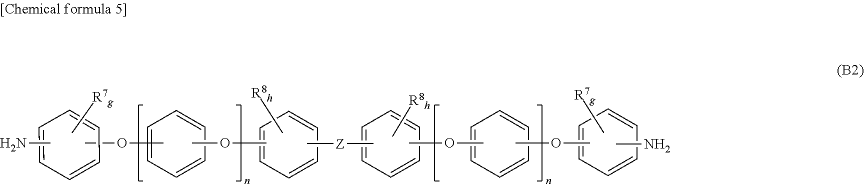

(in the formula (B2),
   Z represents a divalent group selected from the group consisting of an oxygen atom, a methylene group, and —CR^{c}R^{d} (R^{c} and R^{d} each represent a substituted or unsubstituted alkyl group having 1 to 3 carbon atoms),
   each n represents an integer of 0 or 1,
   R⁷ and R⁸ each represent a substituted or unsubstituted alkyl group having 1 to 3 carbon atoms or an alkoxy group having 1 to 3 carbon atoms, and
   g and h each represent an integer of 0 to 3).

[9] The method according to any one of [1] to [8], in which the monomer (A) includes a short-chain diamine α in which the total number of atoms constituting the main chain in the formula (A2) or (A3) is 5 to 20.

[10] The method according to [9], in which the monomer (A) further includes a long-chain diamine β in which the total number of atoms constituting the main chain in the formula (A2) or (A3) is 35 to 500.

[11] The method according to any one of [1] to [10], in which in the forming the resin layer, when the glass transition temperature of the resin layer is denoted by Tg,
the resin layer is formed by applying a resin composition including the polyimide resin or a precursor of the polyimide resin and then heating the resin composition at a temperature of (Tg+150)° C. or lower.

[12] The method according to any one of [1] to [11], in which the board includes silicon or silicon carbide.

[13] A laminate for a semiconductor device, the laminate including: a board having a thickness of 150 μm or less; and a resin layer disposed on the board and including a polyimide resin,
in which the resin layer satisfies equation (1) below:

W=−0.042*X+5.219*Y+0.144*Z−4.434≤31 equation (1):
(in the equation (1), X represents a linear thermal expansion coefficient (CTE) (ppm/K) of the resin layer, Y represents a tensile modulus (GPa) of the resin layer at 23° C., and Z represents a glass transition temperature (° C.) of the resin layer), the polyimide resin includes a polycondensation unit of a tetracarboxylic acid dianhydride and a diamine, and a monomer composed of the tetracarboxylic acid dianhydride and the diamine includes a monomer (A) having an aliphatic chain, the monomer (A) including at least one of a tetracarboxylic acid dianhydride represented by formula (A1), a diamine represented by formula (A2), and a diamine represented by formula (A3), and a monomer (B) having an aromatic ring, the monomer (B) not corresponding to any of the tetracarboxylic acid dianhydride represented by the formula (A1), the diamine represented by the formula (A2), and the diamine represented by the formula (A3):

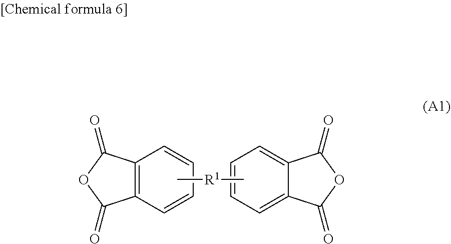

(R¹ in the formula (A1) represents an aliphatic chain having a main chain including at least one atom of C, N, and O, and a total number of atoms constituting the main chain is 4 to 20), and

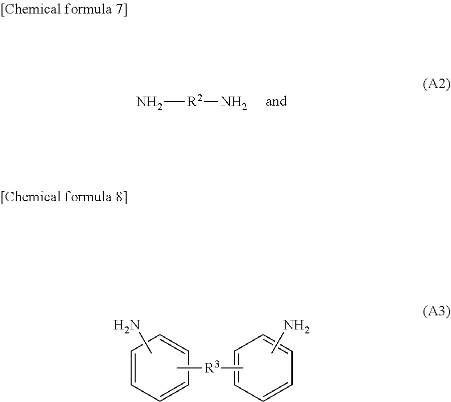

(R² in the formula (A2) and R³ in the formula (A3) each represent an aliphatic chain having a main chain including at least one atom of C, N, and O, and a total number of atoms constituting the main chain is 3 to 500).

[14] The laminate according to [13], in which the CTE of the resin layer is 40 ppm/K or more.

[15] The laminate according to [13] or [14], in which the tensile modulus of the resin layer is 0.5 to 30 GPa.

[16] The laminate according to any one of [13] to [15], in which the glass transition temperature Tg of the resin layer is 250° C. or lower.

[17] The laminate according to any one of [13] to [16], in which the monomer includes 7 to 60 mol % of the monomer (A) and 40 to 93 mol % of the monomer (B) based on a total amount of the monomer.

[18] The laminate according to any one of [13] to [17], in which a thickness of the resin layer is 10 μm or more.

[19] The laminate according to any one of [13] to [18], in which the board includes silicon or silicon carbide.

### Advantageous Effects of Invention

The present invention can provide a method for producing a semiconductor device and a laminate for a semiconductor device, each capable of reducing the bending of a semiconductor wafer, on which a temporary fixing agent is applied, in a producing step of a semiconductor device.

### BRIEF DESCRIPTION OF DRAWINGS

FIGS. 1A to 1F are schematic cross-sectional views illustrating a method for producing a semiconductor device according to an embodiment of the present invention;

FIGS. 2A to 2E are schematic cross-sectional views illustrating the method for producing the semiconductor device according to the embodiment of the present invention; and

FIG. 3A is an explanatory view illustrating a test piece for a tensile test used in Examples, and FIG. 3B is an explanatory view illustrating a method of measuring a curvature radius of a blank wafer in a case of measuring an actual stress.

### DESCRIPTION OF EMBODIMENTS

### 1. Method for Producing Semiconductor Device

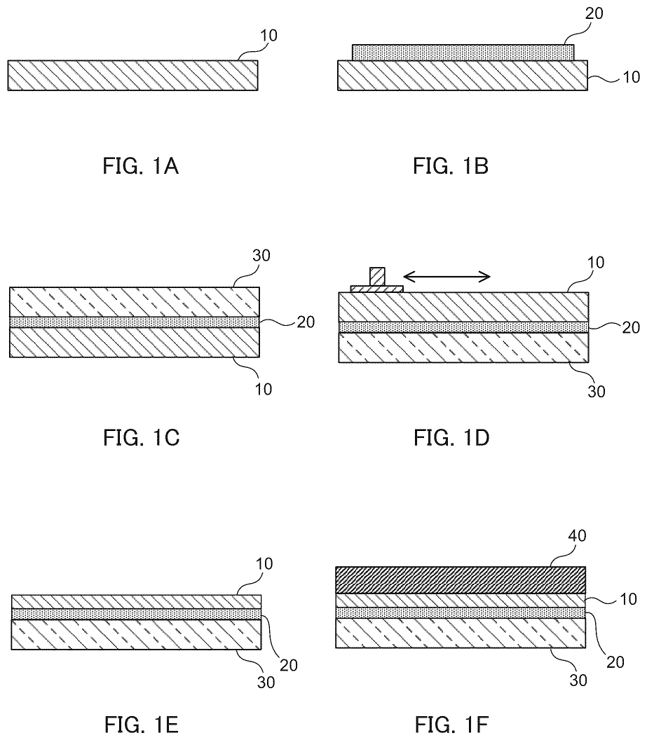

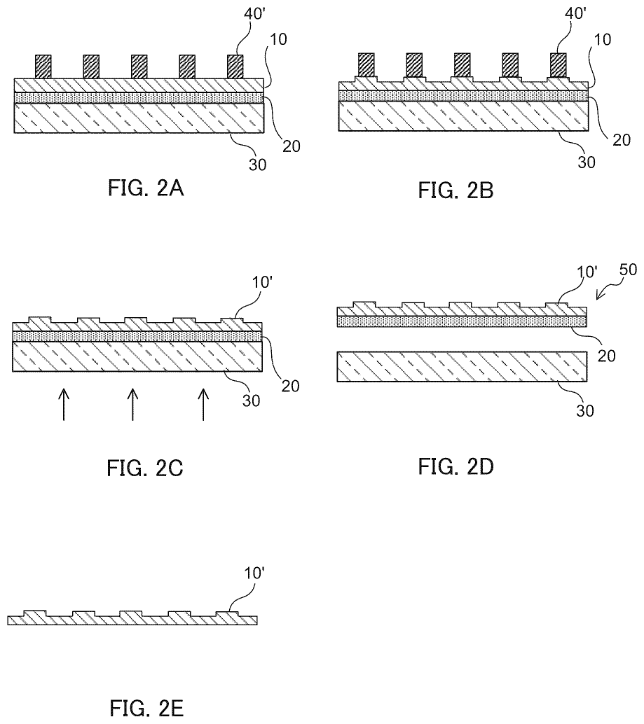

FIGS. 1A to 1F and FIGS. 2A to 2E are schematic views illustrating a method for producing a semiconductor device (herein also referred to as “producing method”) according to an embodiment of the present invention.

As illustrated in FIGS. 1A to 1F and FIGS. 2A to 2E, the method for producing a semiconductor device according to the embodiment of the present invention includes the following: 1) a step (resin layer forming step, FIGS. 1A and 1B) of applying a resin composition onto board 10 and heating the resin composition to form resin layer 20; 2) a step (adhering step, FIG. 1C) of adhering support board 30 on resin layer 20; 3) a step (back surface grinding step, FIGS. 1D and 1E) of grinding a surface of the adhered board 10—the surface located opposite to resin layer 20; 4) a step (back surface processing step, FIG. 1F and FIGS. 2A to 2C) of processing the ground back surface of board 10; 5) a step (peeling step, FIGS. 2C and 2D) of irradiating the bonded board with laser light to peel off support board 30 from resin layer 20; and 6) a step (dissolution step, refer to FIG. 2E) of dissolving and removing the remaining resin layer 20 with a solvent.

### Step 1) (Resin Layer Forming Step)

A resin composition is applied onto board 10 and then heated to form resin layer 20 (FIGS. 1A and 1B). Resin layer 20 can function as a temporary fixing agent for temporarily fixing support board 30 to board 10.

As will be described below, resin layer 20 includes a polyimide resin. Resin layer 20 may be formed by applying a resin composition including a polyimide resin or a precursor thereof and then heating the resin composition. That is, resin layer 20 may be a layer obtained by applying a polyamic acid varnish and then heating the varnish to imidize the polyamic acid, or may be a layer obtained by applying a polyimide varnish and then heating the varnish to dry the varnish. Alternatively, resin layer 20 may be a layer obtained by transferring a polyimide resin film. In the present embodiment, the polyamic acid varnish is applied and then heated to imidize the polyamic acid, thereby forming resin layer 20. The configuration of resin layer 20 and a method of forming resin layer 20 will be described in detail below.

Board 10 may be a semiconductor substrate including at least one member selected from the group consisting of silicon, silicon carbide, gallium nitride, gallium oxide, and sapphire. Among these, a semiconductor substrate including silicon or silicon carbide is preferable. These semiconductor substrates are required to be further thinned. Since the thinned semiconductor substrate is more likely to be bent, the producing method according to the embodiment of the present invention is effective.

A method of applying a varnish may be, for example, a spin coating method.

A method of heating the applied varnish may be, for example, a heating method using an oven or a hot plate.

When a polyamic acid varnish is used as the resin composition, the heating temperature may be any temperature as long as the polyamic acid can be imidized and the solvent can be removed until the varnish becomes an independent film at the temperature. The heating temperature may be, for example, (Tg+150° C.) or lower when the glass transition temperature of resin layer 20 is denoted by Tg. The imidization by heating may be carried out in one stage or two stages.

When the imidization is carried out in one stage, the imidization can be carried out by raising the temperature from a temperature range of 20° C. to 50° C. to a temperature range of Tg to (Tg+150° C.) and maintaining the temperature at a target temperature for a predetermined time. The lower limit value of the target temperature can be set to Tg of resin layer 20 in order to promote the imidization and reduce the residual solvent.

When the imidization is carried out in two stages, the target temperature of the first stage is preferably 50° C. to 150° C. and more preferably 50° C. to 100° C. In addition, the target temperature of the second stage can be the same as described above.

A thickness of resin layer 20 is not particularly limited, but may be a thickness with which support board 30 can be stably fixed to board 10 and unevenness of the surface (circuit forming surface) of board 10 can be filled. From such a viewpoint, the thickness of resin layer 20 is preferably 1 μm or more, more preferably 10 μm or more, and still more preferably 20 μm or more. The upper limit of the thickness of resin layer 20 is not particularly limited, but may be, for example, 100 μm or less, more preferably 90 μm or less, and still more preferably 80 μm or less.

### Step 2) (Adhering Step)

Next, support board 30 is adhered to resin layer 20 (refer to FIG. 1C). Specifically, the heated resin layer 20 and support board 30 thereon are laminated, and then thermally compressed.

Support board 30 may be any board having rigidity, and may be, for example, one of a resin board, a ceramic board, and a glass board. Among these, from the viewpoint of performing LLO, support board 30 is preferably a transparent support board such as a glass board. A thickness of support board 30 is not particularly limited, but is preferably larger than the thickness of resin layer 20, and may be, for example, 50 to 1,000 μm.

The heating temperature of resin layer 20 may be equal to or higher than a melting temperature of resin layer 20. The melting temperature means a melting temperature when resin layer 20 is subjected to viscoelasticity measurement. The melting temperature of the polyimide resin used in the present embodiment may be, for example, 160° C. to 220° C. Specifically, the heating temperature during the adhering may be set to a temperature of the melting temperature or higher and 350° C. or lower.

The method of heating resin layer 20 can be carried out using an oven, a hot plate, or the like, in the same manner as described above. Thermocompression bonding may be carried out by applying a predetermined pressure during the adhering.

### Step 3) (Back Surface Grinding Step)

Next, the surface (back surface) of board 10, to which support board 30 is adhered, is ground—the back surface is located opposite to resin layer 20 (refer to FIGS. 1D and 1E). Thus, the thickness of board 10 is reduced to 150 μm or less, preferably 100 μm or less, and more preferably 70 μm or less. The lower limit value of the thickness of board 10 is not particularly limited, but may be, for example, 10 μm.

### Step 4) (Back Surface Processing Step)

Next, the ground back surface of board 10 is subjected to predetermined processing (refer to FIG. 1F and FIGS. 2A to 2C). In the present embodiment, resist 40 is placed on the polished back surface of board 10 to form resist pattern 40′ (refer to FIG. 1F and FIG. 2A), and board 10 is etched along resist pattern 40′ to be patterned (refer to FIG. 2B).

### Step 5) (Peeling Step)

Next, support board 30 is peeled off from resin layer 20 (refer to FIGS. 2C and 2D). In this manner, patterned board 10′ can be obtained.

A method of peeling off support board 30 is not particularly limited, and support board 30 may be peeled off by a laser irradiation method (laser lift-off (LLO) method) or by mechanical processing. In the present embodiment, support board 30 is peeled off from resin layer 20 by irradiation with laser light.

The laser light may be light having a wavelength of 200 to 360 nm (preferably 355 nm). By the irradiation with the laser light, laser ablation occurs, and thus peeling is facilitated. The polyimide resin included in resin layer 20 preferably includes an ether bond in its molecular chain because the ether bond can be broken and resin layer 20 can be easily peeled off due to heat generated by absorption of an aromatic ring in the polyimide resin included in resin layer 20.

In this manner, by peeling off support board 30, laminate 50 including patterned board 10′ (the board subjected to back surface processing) and resin layer 20 is obtained. In laminate 50, since resin layer 20 also has a function of protecting the surface (circuit forming surface) of board 10′, laminate 50 may be used as it is as a laminate for a semiconductor device, or may be used in another step after resin layer 20 is dissolved and removed as described below.

### Step 6) (Dissolution Step)

Resin layer 20 of laminate 50 is dissolved in a solvent to obtain patterned board 10′ (refer to FIG. 2E).

The solvent to be used may be any solvent capable of dissolving resin layer 20, and examples thereof include N-methyl-2-pyrrolidone (NMP), N,N-dimethylacetamide (DMAc), N,N-dimethylformamide (DMF), 1,3-dimethyl-2-imidazolidinone (DMI), methoxybenzene, and methyl benzoate.

Patterned board 10′ with resin layer 20 has been dissolved and removed may be subjected to a dicing step to be singulated, as necessary.

### 1-1. Bending of Board 10

In the above-described method for producing a semiconductor device, resin layer 20 as a temporary fixing agent is formed by applying a resin composition onto board 10 and then heating the resin composition (step 1 described above). In this case, it is desired that, when resin layer 20 in a heated state is cooled, bending of board 10 on which resin layer 20 is formed can be minimized.

As a method of reducing the bending of board 10, in the related art, in order to suppress deformation of board 10 or reduce a difference in CTE from board 10, it has been common to lower the CTE of a resin layer in contact with board 10. However, according to the studies of the present inventors, it was found that, for resin layer 20 as the temporary fixing agent, surprisingly, increasing the CTE (making resin layer 20 relatively flexible) can significantly reduce the bending of board 10. The reason for this is not clear, but it is considered that, a polyimide resin having a high CTE has a weak force for returning to its molecular structure before heating, and therefore is less likely to deform board 10 even when the temperature of resin layer 20 is changed to cause deformation, thereby preventing the bending of board 10.

Furthermore, according to further studies of the present inventors, it was found that, among physical properties of resin layer 20, the CTE, the tensile modulus, and the glass transition temperature have a particularly large influence on the reduction of the bending of board 10. Based on the above findings, as a result of further studies, it was found that, when W represented by the following equation (1) is 31 or less, the amount of bending of board 10 can be satisfactorily reduced.

That is, resin layer 20 satisfies the relationship of the following equation (1).

$$W = - 0.042 * X + 5.219 * Y + 0.144 * Z - 4.434 \leq 31 \qquad Equation ( 1 )$$

(in the above equation,
X represents a linear thermal expansion coefficient (CTE) (ppm/K) of the resin layer,
Y represents a tensile modulus (GPa) of the resin layer at 23° C., and
Z represents a glass transition temperature (° C.) of the resin layer)

When W represented by the equation (1) is 31 or less, the following bending can be effectively reduced: bending of board 10 during a process of cooling the resin composition after applying and heating the resin composition; and bending of board 10 after peeling off support board 30 after back surface grinding. W represented by the equation (1) is more preferably 28 or less, still more preferably 25 or less, and particularly preferably 23 or less. The lower limit value of W represented by the equation (1) is not particularly limited, but from the viewpoint of easier maintaining of the heat resistance of resin layer 20, the lower limit value is preferably 10 or more and may be 19 or more. From the above viewpoints, W represented by the equation (1) is preferably 10 to 28, more preferably 10 to 25, still more preferably 10 to 23, and particularly preferably 19 to 23.

Hereinafter, resin layer 20 and a resin composition for forming resin layer 20 will be specifically described.

### 1-2. Resin Layer 20

### 1-2-1. Physical Properties

As described above, resin layer 20 functions as a temporary fixing agent for fixing support board 30 and satisfies the relationship of the equation (1). When W represented by the equation (1) is 31 or less, bending of board 10 on which resin layer 20 is formed can be reduced. In order to satisfy the relationship of the equation (1), it is preferable that the CTE of the resin layer is set to be equal to or higher than a predetermined value and the tensile modulus and the glass transition temperature are set to be equal to or lower than predetermined values.

### (CTE)

It is preferable that the CTE of resin layer 20 is high. It is considered that a polyimide resin having a high CTE has a weak force for returning to its molecular structure before heating, and therefore is less likely to deform board 10 even when the temperature of resin layer 20 is changed to cause deformation of resin layer 20, and thus the bending of board 10 can be prevented. Specifically, the CTE of resin layer 20 is preferably 40 ppm/K or more, more preferably 50 to 300 ppm/K, and still more preferably 60 to 150 ppm/K.

The CTE of resin layer 20 can be measured by the following method.

Resin layer 20 is cut into a size of a width of 5 mm and a length of 22 mm.

A linear thermal expansion coefficient (CTE) of the obtained test piece is measured by a thermal analysis device (for example, TMA-60 manufactured by Shimadzu Corporation). Specifically, a measurement is performed in the atmosphere at a temperature rising rate of 5° C./min and a tensile mode (100 mN) to obtain a TMA curve, and a TMA elongation ratio in a temperature range of 50° C. to a heating target temperature (Tg−60° C.) to (Tg−5° C.) (a temperature at which the CTE does not increase rapidly in the vicinity of Tg of resin layer 20) is used as the linear thermal expansion coefficient (CTE).

### (Tensile Modulus)

It is preferable that the tensile modulus of resin layer 20 at 23° C. is low. Resin layer 20 having an appropriately low tensile modulus has high flexibility and is less likely to deform board 10 during cooling, and thus the bending of board 10 on which resin layer 20 is formed is prevented. Specifically, the tensile modulus of resin layer 20 at 23° C. is preferably 0.1 to 50 GPa, more preferably 0.5 to 20.0 GPa, and still more preferably 1.0 to 10.0 GPa.

The tensile modulus of resin layer 20 can be measured by the following method.

The peeled resin layer is punched into a dumbbell shape to form a test piece having the size of A: 50 mm, B: 10 mm, C: 20 mm, and D: 5 mm.

The obtained test piece was set in a tensile test device EZ-S (manufactured by Shimadzu Corporation) and pulled in the length direction (direction A) at 23° C., a speed of 5 mm/min, and a distance between chucks of 30 mm. The stress/strain is used as the elastic modulus.

### (Glass Transition Temperature (Tg))

It is preferable that the glass transition temperature of resin layer 20 is low. This is because, when resin layer 20 is cooled after heating, a temperature difference between the glass transition temperature, which affects the stress generated in the resin, and the temperature after cooling can be reduced, and thus the stress can be reduced and the bending can be further reduced. Specifically, the glass transition temperature of resin layer 20 is preferably 250° C. or lower, more preferably 90° C. to 210° C., and still more preferably 100° C. to 180° C.

The glass transition temperature of resin layer 20 can be measured by the following method.

Resin layer 20 is cut into a size of a width of 5 mm and a length of 22 mm.

A glass transition temperature (Tg) of the obtained test piece is measured by a thermal analysis device (for example, TMA-60 manufactured by Shimadzu Corporation). Specifically, a measurement is performed in the atmosphere at a temperature rising rate of 5° C./min and a tensile mode (100 mN) to obtain a TMA curve, and the value of glass transition temperature (Tg) can be obtained by extrapolating the curves before and after the inflection point derived from glass transition in the TMA curve.

The CTE, the tensile modulus, and the glass transition temperature of resin layer 20 can be adjusted by the composition of the polyimide resin in resin layer 20. Specifically, it is preferable to increase the proportion of an aliphatic monomer (a diamine represented by formula (A2) described below) in the polyimide resin or an aromatic monomer having a flexible skeleton (a tetracarboxylic acid dianhydride represented by formula (A1) described below or a diamine represented by formula (A3) described below). It is considered that, since the molecular alignment is small, the force for returning to its molecular structure before heating is weak, and even when the temperature of resin layer 20 is changed to cause deformation, board 10 is less likely to be deformed, and thus the bending of board 10 can be prevented.

### (Thermal Decomposition Temperature (T_{d5}))

From the above viewpoints, a thermal decomposition temperature (T_{d5}) of resin layer 20 in an atmospheric environment is preferably 400° C. or higher, more preferably 450° C. or higher, and still more preferably 460° C. or higher. The upper limit of T_{d5} of resin layer 20 is not particularly limited, but may be, for example, 600° C.

The thermal decomposition temperature (T_{d5}) of the resin layer can be measured using a thermogravimetric analyzer (for example, TGA-60, manufactured by Shimadzu Corporation).

Specifically, resin layer 20 (approximately 5 mg) is accurately weighed on the device, a scanning temperature is set to 30° C. to 900° C., and resin layer 20 is heated under a condition of a temperature rising rate of 10° C./min while allowing an air gas to flow at 50 mL/min in an atmospheric environment, and a temperature at which the mass of the sample is reduced by 5% is used as T_{d5}.

### (Solubility)

In a case of using resin layer 20 as a temporary fixing agent, from the viewpoint of easily dissolving resin layer 20 in a solvent to peel off resin layer 20, it is preferable that the solubility in the solvent is high. Specifically, a dissolution rate of resin layer 20 measured by immersing resin layer 20 in N-methyl-2-pyrrolidone at 80° C. for 3 minutes and then filtering the solution through filter paper is preferably 60% or more, more preferably 85% or more, and still more preferably 90% or more.

The solubility can be measured by the following method.

1) The peeled resin layer is cut into a size of 2.0 cm×2.0 cm to form a test piece, and the weight thereof (the weight of the test piece before immersion) is measured in advance. In addition, the weight of the filter paper before use is also measured in advance.

2) Next, the test piece is added to N-methyl-2-pyrrolidone (in an amount such that the content of the test piece is 1% by mass, 5 to 7 mL in this case) to prepare a sample solution, and the obtained sample solution is allowed to stand for 3 minutes in an oven heated to 80° C. Thereafter, the sample solution is taken out from the oven, filtered through filter paper (roughness of mesh: 5B), and then dried under reduced pressure at 100° C. The weight of the filter paper after filtration and drying is then measured.

3) The dissolution rate is calculated by applying the measured values of 1) and 2) to equation (2). These operations (the operations 1) to 3) described above) are performed twice, and the average value thereof is used as the dissolution rate (%).

Dissolution rate (%)=[1−[(Weight of filter paper after filtration and drying)−(Weight of filter paper before use)]/(Weight of test piece before immersion)]×100 Equation (2):

The T_{d5} and the solubility of resin layer 20 can also be adjusted by the composition of the polyimide resin in resin layer 20. For example, in the polyimide resin, when the proportion of an aliphatic monomer (a diamine represented by formula (A2) described below) or an aromatic monomer having a flexible skeleton (a tetracarboxylic acid dianhydride represented by formula (A1) described below or a diamine represented by formula (A3) described below) is increased, T_{d5} is more likely to be lowered and the solubility is more likely to be increased.

These physical properties of resin layer 20 may correspond to the physical properties of the polyimide resin.

### 1-2-2. Composition

Resin layer 20 includes a polyimide resin.

The polyimide resin includes a polycondensation unit of a tetracarboxylic acid dianhydride and a diamine. The monomer composed of the tetracarboxylic acid dianhydride and the diamine includes a monomer (A) having an aliphatic chain and a monomer (B) having an aromatic ring and having no aliphatic chain.

### <Monomer (A)>

The monomer (A) is a monomer having an aliphatic chain. Specifically, the aliphatic chain is an aliphatic chain having a main chain that does not include an aromatic ring and includes at least one atom of C, N, and O, and the total number of atoms constituting the main chain is 3 or more. The main chain is a portion of the aliphatic chain, the portion composed of atoms other than atoms constituting a side chain. Such a monomer (A) tends to impart an appropriate degree of flexibility to polyimide, tends to increase the CTE, and tends to decrease the tensile modulus and Tg. In addition, the monomer (A) may have an aromatic ring in a portion other than the aliphatic chain. The monomer (A) may be a tetracarboxylic acid dianhydride or a diamine.

Examples of the tetracarboxylic acid dianhydride include a tetracarboxylic acid dianhydride represented by formula (A1).

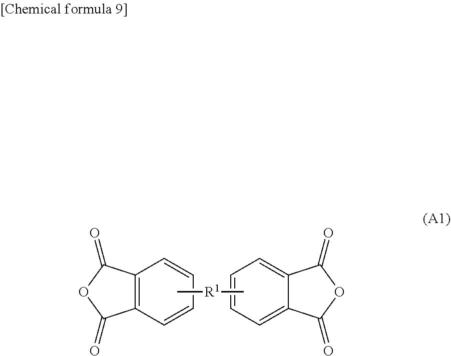

R¹ in the formula (A1) is an aliphatic chain having a main chain including at least one atom of C, N, and O, and the total number of atoms constituting the main chain is 4 to 20. In particular, R¹ is preferably a linear alkylene group or a linear alkylene dioxy group each having 4 to 20 carbon atoms, and more preferably a linear alkylene group having 4 to 20 carbon atoms.

Examples of the tetracarboxylic acid dianhydride represented by the formula (A1) include a compound represented by the formula (A1-1), and preferably include the compound represented by formula (A1-1′) (BSPA8, 5,5′-(octane-1,8-diyl)bis(isobenzofuran-1,3-dione)).

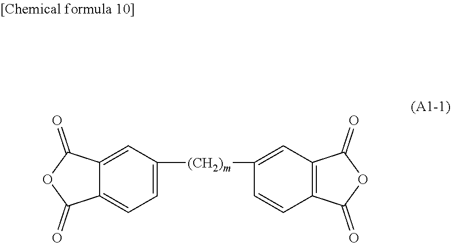

(in the formula (A1-1), m represents an integer of 4 to 12)

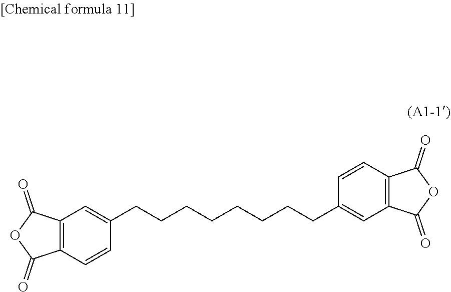 [SMILES: O=C1OC(=O)c2cc(CCCCCCCCc3ccc4c(c3)C(=O)OC4=O)ccc21]

Other examples of the tetracarboxylic acid dianhydride represented by the formula (A1) include 5,5′-[1,2-ethanediylbis(oxy)]bis[1,3-isobenzofurandione], 5,5′-[1,3-propanediylbis(oxy)]bis[1,3-isobenzofurandione], and 5,5′-[1,4-butanediylbis(oxy)]bis[1,3-isobenzofurandione].

Examples of the diamine include a diamine represented by the formula (A2) or (A3).

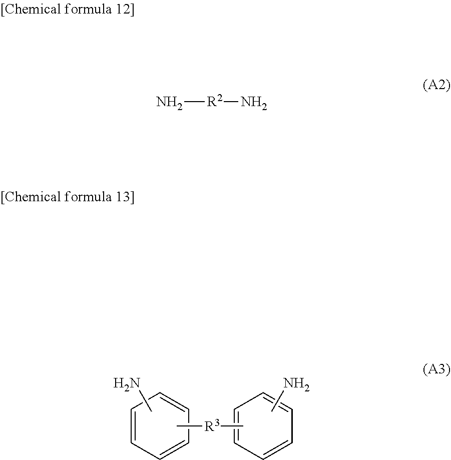

R² in the formula (A2) and R³ in the formula (A3) each represent an aliphatic chain having a main chain including at least one atom of C, N, and O, and the total number of atoms constituting the main chain is 3 to 500.

Examples of the main chain including at least one atom of C, N, and O include the following: a main chain having a structure derived from a polyalkylene polyamine such as diethylenetriamine, triethylenetetramine, or tetraethylenepentamine; an alkylene main chain; a main chain having an alkyl ether structure; a main chain having a polyalkylene carbonate structure; and a main chain having an alkyleneoxy group or a polyalkyleneoxy group.

The polyalkyleneoxy group in the main chain having an alkyleneoxy group or a polyalkyleneoxy group is a divalent linking group including an alkyleneoxy as a repeating unit, and examples thereof include “—(CH₂CH₂O)ₙ—” including an ethyleneoxy unit as a repeating unit and “—(CH₂—CH(—CH₃)O)ₘ—” including a propyleneoxy unit as a repeating unit (where n and m are the number of repetitions).

The number of carbon atoms in an alkylene moiety of the alkyleneoxy group and an alkylene moiety of the alkyleneoxy unit constituting the polyalkyleneoxy group is preferably 2 to 10. Examples of an alkylene group constituting the alkyleneoxy group include an ethylene group, a propylene group, and a butylene group.

The aliphatic chains represented by R² and R³ may further have a side chain including at least one atom of C, N, H, and O. The side chain is a monovalent group linked to an atom in the main chain. The total number of atoms constituting the side chain is preferably 10 or less. Examples of such a side chain include an alkyl group such as a methyl group.

Examples of the diamine represented by the formula (A2) include a linear alkylene diamine and a linear (poly)alkylene oxydiamine.

Examples of the linear alkylene diamine include a linear alkylene diamine having 6 to 12 carbon atoms, preferably 6 to 10 carbon atoms, such as 1,6-diaminohexane, 1,7-diaminoheptane, 1,8-diaminooctane, 1,9-diaminononane, 1,10-diaminodecane, 1,11-diaminoundecane, or 1,12-diaminododecane.

Examples of the linear (poly)alkylene oxydiamine include a linear (poly)alkylene oxydiamine having 4 to 12 carbon atoms such as 1,8-diamino-3,6-dioxa-octane, 4,9-dioxane-1,12-dodecanediamine, or 1,13-diamino-4,7,10-trioxatridecane; and a (poly)alkylene oxydiamine having 20 to 70 carbon atoms such as a compound represented by formula (A2-1).

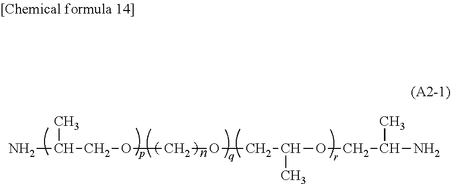

(p, q, and r each independently represent an integer of 0 to 12; provided that p+q+r is 1 or more and is preferably 5 to 20)

Examples of the diamine represented by the formula (A3) include a compound represented by formula (A3-1).

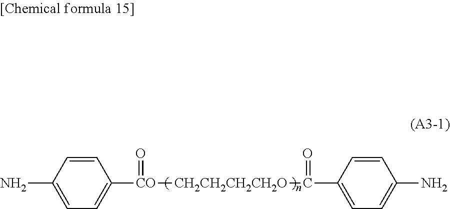

(n represents an integer of 1 to 50, and preferably represents an integer of 10 to 20)

The monomer (A) includes at least one of the tetracarboxylic acid dianhydride represented by the formula (A1), the diamine represented by the formula (A2), and the diamine represented by the formula (A3). Among these, the monomer (A) preferably includes the diamine represented by the formula (A2) or (A3), and more preferably includes the diamine represented by the formula (A2).

When the monomer (A) includes the diamine represented by the formula (A2) or (A3), the diamine represented by the formula (A2) or (A3) preferably includes a short-chain diamine α in which the total number of atoms constituting the main chain in the formula (A2) or (A3) is 5 to 20; and more preferably further includes a long-chain diamine β in which the total number of atoms constituting the main chain in the formula (A2) or (A3) is 35 to 500.

In the short-chain diamine α, the total number of atoms constituting the main chain is 5 to 20, preferably 5 to 18, more preferably 8 to 14, and still more preferably 8 to 12. The main chain of R² is a chain composed of atoms of the aliphatic chain connecting the two amino groups located at the molecular terminals, except for the atoms constituting the side chains. Since the main chain of the short-chain diamine α is short, the decrease in heat resistance can be further reduced.

Examples of the short-chain diamine α include the above-described linear alkylene diamine having 4 to 12 carbon atoms or the linear (poly)alkylene oxydiamine having 6 to 12 carbon atoms.

In the long-chain diamine β, the total number of atoms constituting the main chain is 35 to 500, preferably 40 to 400, more preferably 40 to 300, and still more preferably 50 to 100. Since the long-chain diamine β has a long main chain, the bending of board 10 can be further reduced.

Examples of the long-chain diamine β include a (poly)alkylene oxydiamine having 20 to 70 carbon atoms, such as a compound represented by the formula (A2-1), and a compound represented by the formula (A3-1) described above.

When the diamine represented by the formula (A2-1) is the long-chain diamine β, 3p+q×(n+1)+3r+2 in the formula (A2-1) is 35 to 500, preferably 40 to 400, and more preferably 50 to 100. Examples of the diamine represented by the formula (A2-1) include RT1000 or ED900 (polyetheramine, both manufactured by Huntsman Corporation).

When the monomer (A) includes both the short-chain diamine α and the long-chain diamine β, it is preferable that the main chain of the long-chain diamine β includes an ether bond and the main chain of the short-chain diamine α does not include an ether bond. This is because the diamine including an ether bond not only further increases the flexibility of the polyimide resin but also includes a large amount of ether bonds that are decomposed by heat generated when the aromatic ring absorbs the laser light, and thus the peelability by LLO is easily further enhanced. When the short-chain diamine α does not include an ether bond, the main chain is preferably an alkylene chain and more preferably a linear alkylene chain having no branched structure.

A ratio Mα/Mβ of a content Mα of the short-chain diamine α to a content Mβ of the long-chain diamine β is preferably 100/0 to 60/40 (molar ratio), and more preferably 90/10 to 70/30. When Mα/Mβ is large, the proportion of the short-chain diamine α is increased, and thus the decrease in heat resistance is more easily prevented. When Mα/Mβ is small, the proportion of the long-chain diamine β is increased, and thus the effect of suppressing the bending is more easily obtained. In addition, in a case where the short-chain diamine α does not include an ether bond and the long-chain diamine β includes an ether bond, when Mα/Mβ is small, the proportion of the long-chain diamine β including an ether bond is increased, and thus the peelability by laser lift-off (LLO) can be further enhanced.

The content of the monomer (A) in the polyimide resin is preferably 7 to 60 mol % based on the total amount of monomers in the polyimide resin. When the content of the monomer (A) is 7 mol % or more, the polyimide resin tends to have an appropriate degree of flexibility, and the bending of board 10 can be further prevented. When the content of the monomer (A) is 60 mol % or less, the heat resistance of the polyimide resin is less likely to be impaired. From the same viewpoint, the content of the monomer (A) is more preferably 15 to 50 mol % based on the total amount of monomers in the polyimide resin.

### <Monomer (B)>

The monomer (B) is a monomer having an aromatic ring and not having any of the above-described aliphatic chains. Specifically, the monomer (B) is a monomer having an aromatic ring, which does not correspond to any of the tetracarboxylic acid dianhydride represented by the formula (A1), the diamine represented by the formula (A2), and the diamine represented by the formula (A3). Such a monomer (B) can make it easier to maintain the heat resistance of the polyimide resin. The monomer (B) may be a tetracarboxylic acid dianhydride or a diamine.

The monomer (B) is preferably an aromatic tetracarboxylic acid dianhydride or an aromatic diamine each having a diphenyl ether skeleton. This is because the heat resistance and flexibility of the obtained polyimide resin can be improved in a well-balanced manner. It is preferable that the aromatic tetracarboxylic acid dianhydride and the aromatic diamine each having a diphenyl ether skeleton have three or more aromatic rings.

Examples of such an aromatic tetracarboxylic acid dianhydride include an aromatic tetracarboxylic acid dianhydride represented by formula (B1), and examples of such an aromatic diamine include an aromatic diamine represented by formula (B2). That is, the monomer (B) preferably includes at least one of the aromatic tetracarboxylic acid dianhydride represented by the formula (B1) and the aromatic diamine represented by the formula (B2).

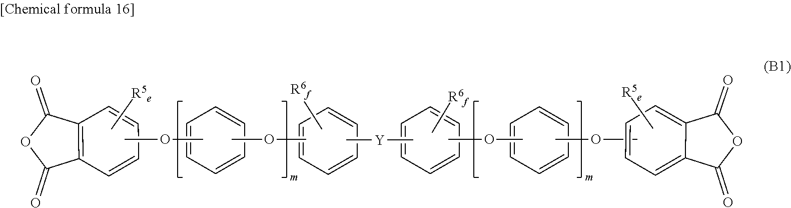

In the formula (B1), Y represents a divalent group selected from the group consisting of an oxygen atom, a methylene group, and —CR^{a}R^{b} (R^{a} and R^{b} each represent a substituted or unsubstituted alkyl group having 1 to 3 carbon atoms), preferably-CR^{a}R^{b} and more preferably —C(CH₃)₂. Each m represents an integer of 0 or 1, and is preferably 0.

R⁵ and R⁶ each represent a substituted or unsubstituted alkyl group having 1 to 3 carbon atoms or an alkoxy group having 1 to 3 carbon atoms, and are preferably a methyl group or a methoxy group. Each of e and f represents an integer of 0 to 3, and is preferably 0 or 1.

Examples of the aromatic tetracarboxylic acid dianhydride represented by the formula (B1) include 4,4′-(4,4′-isopropylidenediphenoxyl)bis(phthalic acid anhydride) (pBPADA).

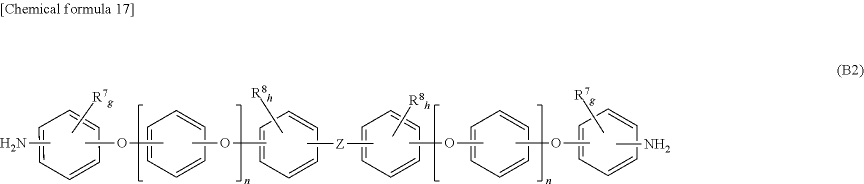

Z, R⁷, R⁸, n, g, and h in the formula (B2) respectively have the same meaning as Y, m, R⁵, R⁶, e, and f in the formula (B1).

Examples of the aromatic diamine represented by the formula (B2) include bis[4-(3-aminophenoxy)phenyl]methane, bis[4-(4-aminophenoxy)phenyl]methane, 2,2-bis[4-(3-aminophenoxy)phenyl]propane, and 2,2-bis[4-(4-aminophenoxy)phenyl]propane.

The sum of the amount of the aromatic tetracarboxylic acid dianhydride represented by the formula (B1) and the amount of the aromatic diamine represented by the formula (B2) is not particularly limited, but is preferably 60 mol % or more based on the total amount of the monomer (B). When the above-described sum is 60 mol % or more, not only can the heat resistance be further improved, but also the flexibility is less likely to be impaired, and thus the effect of suppressing the bending is less likely to be impaired. From the same viewpoint, the above-described sum is more preferably 80 mol % or more based on the total amount of the monomer (B).

The monomer (B) may further include another aromatic monomer in addition to the above-described aromatic monomers, within a range in which the effect of the present invention is not impaired. Examples of the other aromatic monomers include other aromatic tetracarboxylic acid dianhydrides and other aromatic diamines other than the above-described aromatic monomers.

Examples of the other aromatic tetracarboxylic acid dianhydrides include
an aromatic tetracarboxylic acid dianhydride having a biphenyl skeleton, such as 3,3′,4,4′-biphenyltetracarboxylic acid dianhydride;
an aromatic tetracarboxylic acid dianhydride having a diphenyl ether skeleton other than the aromatic tetracarboxylic acid dianhydride represented by the formula (B1), such as 1,3-bis(3,4-dicarboxyphenoxy)benzene dianhydride, 1,4-bis(3,4-dicarboxyphenoxy)benzene dianhydride, or 4,4′-oxydiphthalic acid anhydride;
an aromatic tetracarboxylic acid dianhydride having a benzophenone skeleton, such as 3,3′,4,4′-benzophenone tetracarboxylic acid dianhydride;
an aromatic tetracarboxylic acid dianhydride having a hexafluoroisopropylidene skeleton, such as 2,2-bis(2,3-dicarboxyphenyl)-1,1,1,3,3,3-hexafluoropropane dianhydride (6FDA); and
an aromatic tetracarboxylic acid dianhydride having a fluorene skeleton, such as 9,9-bis(3,4-dicarboxyphenyl) fluorene dianhydride (BPAF).

These aromatic tetracarboxylic acid dianhydrides have an appropriate degree of rigidity, and thus it is easy to improve the heat resistance (particularly T_{d5}) of the obtained polyimide. Among these, from the viewpoint of further enhancing the heat resistance, an aromatic tetracarboxylic acid dianhydride having a biphenyl skeleton is preferable.

Examples of the other aromatic diamines include an aromatic diamine having a diphenyl ether skeleton other than the aromatic diamine represented by the formula (B2), such as 1,3-bis(3-aminophenoxy)benzene (APB-N), 1,3-bis(4-aminophenoxy)benzene, or 2,2-bis[4-(4-aminophenoxy)phenyl]propane.

The content of the monomer (B) in the polyimide resin is preferably 40 to 93 mol % based on the total amount of monomers in the polyimide resin. When the content of the monomer (B) is 40 mol % or more, the heat resistance of the polyimide resin can be further enhanced, and thus it is possible to sufficiently withstand, for example, a high-temperature process after back surface grinding. When the content of the monomer (B) is 93 mol % or less, the flexibility of the polyimide resin is less likely to be impaired, and thus the effect of suppressing the bending of board 10 is less likely to be impaired. From the same viewpoint, the content of the monomer (B) is more preferably 50 to 85 mol % based on the total amount of monomers in the polyimide resin.

### <Physical Properties and the Like of Polyimide Resin>

The molecular terminal of the polyimide resin may be either an acid anhydride group or an amino group. From the viewpoint of increasing the solubility of resin layer 20 including the polyimide resin, it is preferable that the proportion of the molecular terminal which is an acid anhydride group is larger than the proportion of the molecular terminal which is an amino group. In order to increase the proportion of the molecular terminal which is an acid anhydride group, the amount (a mol) of the tetracarboxylic acid dianhydride component to be reacted may be larger than the amount (b mol) of the diamine component to be reacted. Specifically, a molar ratio (b/a) of the diamine (b mol) and the tetracarboxylic acid dianhydride (a mol) in the polyimide resin is not particularly limited, but is preferably 0.90 to 0.999 and may be 0.90 to 0.95. When b/a is 0.999 or less, it is easy to make the molecular terminal an acid anhydride group, and thus the solubility of resin layer 20 including the polyimide resin is easily obtained. The ratio b/a can be specified as the charging ratio between the tetracarboxylic acid dianhydride component to be reacted (a mol) and the diamine component to be reacted (b mol).

From the viewpoint of easily forming a film, the intrinsic viscosity n of the polyimide resin is preferably 0.3 to 2.0 dl/g and more preferably 0.5 to 1.5 dl/g. The intrinsic viscosity (η) of the polyimide resin is the average value of measurements taken three times at 25° C. using an Ubbelohde viscometer when the polyamic acid is dissolved in N-methyl-2-pyrrolidone (NMP) to a concentration of 0.5 g/dL.

The intrinsic viscosity (η) of the polyimide resin can be adjusted by the molar ratio (b/a) of the diamine (b mol) and the tetracarboxylic acid dianhydride (a mol) in the polyimide resin. By setting the molar ratio (b/a) within the above-described range, it is possible to obtain an appropriate solid content concentration while keeping n appropriately small, so that it is easy to form a satisfactorily thick resin layer 20 including the polyimide resin.

The content of the polyimide resin in resin layer 20 is preferably 80% by mass or more with respect to resin layer 20, may be 90% to 100% by mass, and may be 95% to 100% by mass.

Resin layer 20 may further include another component in addition to the polyimide resin, as necessary.

### 1-2-3. Forming Method

Resin layer 20 may be a layer obtained by applying a polyamic acid varnish as a resin composition and then heating the varnish to imidize the polyamic acid, or may be a layer obtained by applying a polyimide varnish as a resin composition and then heating the varnish to dry the varnish. In the present embodiment, resin layer 20 may be a layer obtained by applying a polyamic acid varnish as a resin composition and then heating the varnish to imidize the polyamic acid.

The polyamic acid varnish includes a polyamic acid obtained from the above-described monomer and a solvent.

### (Polyamic Acid)

The polyamic acid is a precursor of the above-described polyimide resin. The composition and physical properties of the polyamic acid are the same as the composition and physical properties of the polyimide resin.

### (Solvent)

The solvent may be a solvent used for preparing the polyamic acid, and is not particularly limited as long as the solvent can dissolve the above-described diamine component and tetracarboxylic acid dianhydride component. For example, an aprotic polar solvent or an alcohol-based solvent can be used.

Examples of the aprotic polar solvent include N-methyl-2-pyrrolidone, N,N-dimethylformamide, dimethyl sulfoxide, N,N-dimethylacetamide, hexamethylphosphoramide, 1,3-dimethyl-2-imidazolidinone, 3-methoxy-N,N-dimethylpropanamide, γ-butyrolactone, ε-caprolactone; and ether-based compounds such as 2-methoxyethanol, 2-ethoxyethanol, 2-(methoxymethoxy) ethoxyethanol, 2-isopropoxyethanol, 2-butoxyethanol, tetrahydrofurfuryl alcohol, diethylene glycol, diethylene glycol monomethyl ether, diethylene glycol monoethyl ether, diethylene glycol monobutyl ether, triethylene glycol, triethylene glycol monoethyl ether, tetraethylene glycol, 1-methoxy-2-propanol, 1-ethoxy-2-propanol, dipropylene glycol, dipropylene glycol monomethyl ether, dipropylene glycol monoethyl ether, tripropylene glycol monomethyl ether, polyethylene glycol, polypropylene glycol, tetrahydrofuran, dioxane, 1,2-dimethoxyethane, diethylene glycol dimethyl ether, and diethylene glycol diethyl ether.

Examples of the alcohol-based solvent include methanol, ethanol, 1-propanol, 2-propanol, tert-butyl alcohol, ethylene glycol, 1,2-propanediol, 1,3-propanediol, 1,3-butanediol, 1,4-butanediol, 2,3-butanediol, 1,5-pentanediol, 2-butene-1,4-diol, 2-methyl-2,4-pentanediol, 1,2,6-hexanetriol, and diacetone alcohol.

These solvents may be used individually or in combination. Among these, N,N-dimethylacetamide, N-methyl-2-pyrrolidone, 1,3-dimethyl-2-imidazolidinone, 3-methoxy-N,N-dimethylpropanamide, γ-butyrolactone, dimethyl sulfoxide, or a mixed solvent of two or more of these solvents is preferable.

From the viewpoint of improving coatability, a concentration of resin solid contents in the polyamic acid varnish is preferably 5% to 50% by mass and more preferably 10% to 40% by mass.

### 1-3. Effects

In the above-described method for producing a semiconductor device, resin layer 20 including the above-described polyimide composition satisfies the relationship of the equation (1). As a result, for example, in the step 1) (resin layer forming step), bending of board 10 on which resin layer 20 is formed can be prevented during a process of cooling the the resin composition after applying and heating the resin composition, and thus poor adhesion of support board 30 can be prevented. In particular, by setting the glass transition temperature of resin layer 20 to be equal to or lower than a certain temperature, bending of board 10 on which resin layer 20 is formed can be further reduced.

In addition, in the step 4) (back surface processing step), board 10 is exposed to a high temperature of 200° C. or higher, but even in such a high-temperature process, the bending of board 10 on which resin layer 20 is formed can be reduced, and damage can be prevented.

In particular, in order to fill the unevenness of the surface (circuit forming surface) of board 10, it is desired to increase the thickness of resin layer 20. Even in such a case, by configuring resin layer 20 as described above, the bending of board 10 can be prevented even when the thickness of resin layer 20 is large.

Furthermore, since resin layer 20 has relatively high flexibility, the solubility in a solvent is also excellent. Therefore, in the step 6) (dissolution step), resin layer 20 remaining after support board 30 is peeled off by LLO can be dissolved and removed.

### 2. Laminate for Semiconductor Device

In the step 5) (peeling step) of the above-described method for producing a semiconductor device, laminate 50 including patterned board 10′ (the board subjected to back surface processing) and resin layer 20 is obtained.

In the present embodiment, laminate 50 is configured such that resin layer 20 satisfies the equation (1). Therefore, the thickness of board 10 is reduced to 150 μm or less, and the bending of laminate 50 is reduced even though laminate 50 is exposed to the high-temperature process. Therefore, even when laminate 50 is peeled off from support board 30, the damage or the like to board 10 can be prevented, thereby improving the handleability.

The laminate for a semiconductor device is preferably used for producing semiconductor devices such as a diode, a transistor, an integrated circuit (IC), and a power element. In particular, in the power element, board 10 is further thinned, and thus the reduction in bending is further desired. The method for producing a semiconductor device and the laminate for a semiconductor device according to the embodiment of the present invention are particularly effective for producing such a semiconductor device.

### 3. Variations

In the above-described method for producing a semiconductor device according to the embodiment described above, the producing process including the step 4) (back surface processing step) and the step 6) (dissolution step) is shown, but these steps may be optionally performed or may be omitted. In addition, in the step 4) (back surface processing step), an example of the patterning processing is shown, but the present invention is not limited thereto. For example, processing different from the above-described processing may be performed, such as forming a collector layer to form an insulated gate bipolar transistor (IGBT) after performing ion implantation or annealing.

In addition, in the above-described embodiment, laminate 50 including board 10 which has been subjected to back surface grinding is described, but a laminate including board 10 before being subjected to back surface grinding may be distributed.

### EXAMPLES

Hereinafter, the present invention will be described with reference to Examples. The scope of the present invention is not interpreted to be limited by the Examples.

### 1. Preparation of Materials

### 1-1. Monomer (A)

### (Tetracarboxylic Acid Dianhydride)

BSPA8: 5,5′-(octane-1,8-diyl)bis(isobenzofuran-1,3-dione)

### (Diamine)

10DA: 1,10-diaminodecane
Dioxadiamine: 4,9-dioxane-1,12-dodecanediamine
HMDA: 1,6-diaminohexane
RT1000: polyetheramine (manufactured by Huntsman Corporation, refer to the following formula, Mw=1015)

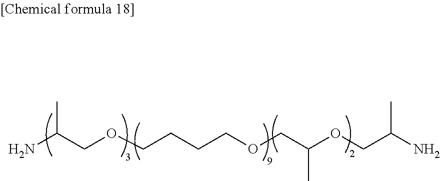

Elasomer 1000P: polyether diamine (manufactured by Ihara Chemical Co., Ltd., amine value: 80 to 90, refer to the following formula, Mw=1268)

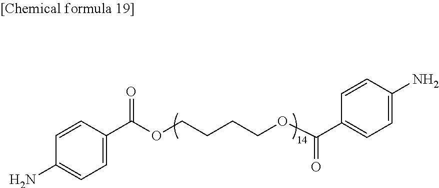

### 1-2. Monomer (B)

### (Tetracarboxylic Acid Dianhydride)

pBPADA: 4,4′-(4,4′-isopropylidenediphenoxyl)bis(phthalic acid anhydride)
s-BPDA: 3,3′,4,4′-biphenyltetracarboxylic acid dianhydride
BTDA: 3,3′,4,4′-benzophenone tetracarboxylic acid dianhydride

### (Diamine)

p-BAPP: 2,2-bis(4-(4-aminophenoxy)phenyl)propane
APB-N: 1,3-bis(3-aminophenoxy)benzene

### 1-3. Solvent

NMP: N-methyl-2-pyrrolidone

### 2. Preparation and Evaluation of Samples

### (Preparation of Polyamic Acid Varnishes 1 to 11)

A tetracarboxylic acid dianhydride and a diamine were blended in N-methyl-2-pyrrolidone in the amounts (mol %) as shown in Table 1. The obtained mixture was stirred at 45° C. to 85° C. for 5 hours or more in a flask that allows introduction of a dry nitrogen gas thereto, thereby obtaining each of polyamic acid varnishes 1 to 11 having a resin solid content of 20% to 30% by mass.

### (Preparation of Samples)

The obtained varnish was applied onto a 4-inch silicon wafer such that a dry thickness was 9 to 11 μm, and then heated under the following conditions to prepare a sample with a resin layer including a polyimide resin. A plurality of samples were prepared for each varnish.
Oven: After heating a sample on a hot plate at 80° C. for 5 minutes, the sample was moved to an oven separately heated to 50° C., the temperature was raised to a film forming temperature at the rate of 5° C./min, and the sample was held at the film forming temperature for 30 minutes.
Hot plate: After heating a sample at 80° C. for 5 minutes, the sample was moved to a hot plate separately heated to the film forming temperature and held for 5 minutes.

### (Evaluation)

The resin layer was peeled off from the obtained sample, and the physical properties (glass transition temperature, CTE, elastic modulus, thermal decomposition temperature, and solubility) of the resin layer were measured by the methods below. In addition, the amount of bending of the sample was also evaluated by the method below.

### (1) Glass Transition Temperature (Tg)

The peeled resin layer was cut into a size of a width of 5 mm and a length of 22 mm to form a test piece.

A glass transition temperature (Tg) of the test piece was measured with a thermal analysis device TMA-60 (manufactured by Shimadzu Corporation). Specifically, a measurement was performed in the atmosphere at a temperature rising rate of 5° C./min and a tensile mode (100 mN) to obtain a TMA curve, and the value of the glass transition temperature (Tg) was obtained by extrapolating the curves before and after the inflection point derived from glass transition in the TMA curve.

### (2) CTE

The peeled resin layer was cut into a size of a width of 5 mm and a length of 22 mm to form a test piece.

A linear thermal expansion coefficient (CTE) of the test piece was measured with a thermal analysis device TMA-60 (manufactured by Shimadzu Corporation). Specifically, a measurement is performed in the atmosphere at a temperature rising rate of 5° C./min and a tensile mode (100 mN) to obtain a TMA curve, and a TMA elongation ratio at a temperature range of 50° C. to a heating target temperature (Tg-60° C.) to (Tg-5° C.) (a temperature at which the CTE does not increase rapidly in the vicinity of Tg) was used as the linear thermal expansion coefficient (CTE).

### (3) Tensile Modulus

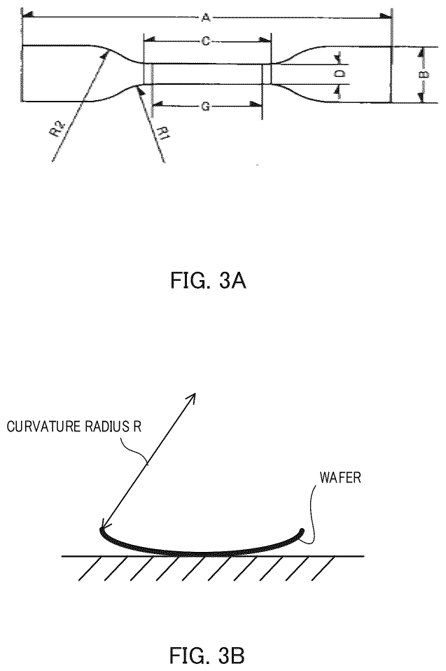

The peeled resin layer was punched into a dumbbell shape as illustrated in FIG. 3A to form a test piece having the size of A: 50 mm, B: 10 mm, C: 20 mm, and D: 5 mm.

The obtained test piece was set in a tensile test device EZ-S (manufactured by Shimadzu Corporation) and pulled in the length direction (direction A) at 23° C., a speed of 5 mm/min, and a distance between chucks of 30 mm. Then, the tensile modulus was obtained from the inclination of the stress-strain curve in the elastic region.

### (4) Thermal Decomposition Temperature (T_{d5})

A 5% weight loss temperature (T_{d5}) of the resin layer was measured using a thermogravimetric analyzer TGA-60 (manufactured by Shimadzu Corporation).

Specifically, the peeled resin layer (approximately 5 mg) was accurately weighed on the device, a scanning temperature was set to 30° C. to 900° C., and the resin layer was heated under a condition of a temperature rising rate of 10° C./min while allowing an air gas to flow at 50 mL/min in an atmospheric environment, and a temperature at which the mass of the sample was reduced by 5% was used as T_{d5}.

### (5) Solubility

The solubility of the resin layer was evaluated by the following procedure.

1) The peeled resin layer was cut into a size of 2.0 cm×2.0 cm to form a test piece, and the weight thereof (the weight of the test piece before immersion) was measured in advance. In addition, the weight of the filter paper before use was also measured in advance.

2) Next, the test piece was added to N-methyl-2-pyrrolidone (in an amount such that the content of the test piece is 1% by mass, 5 to 7 mL in this case) to prepare a sample solution, and the obtained sample solution was allowed to stand for 3 minutes in an oven heated to 80° C. Thereafter, the sample solution was taken out of the oven, filtered through filter paper (roughness of mesh: 5B), and then dried under reduced pressure at 100° C. The weight of the filter paper after filtration and drying was then measured.

3) The dissolution rate was calculated by applying the measured values of 1) and 2) to equation (2). These operations (the operations 1) to 3) described above) were performed twice, and the average value thereof was used as the dissolution rate (%).

Dissolution rate (%)=[1−[(Weight of filter paper after filtration and drying)−(Weight of filter paper before use)]/(Weight of test piece before immersion)]×100 Equation (2):

### (6) Actual Stress

1) The 4-inch silicon wafer was set in a stress measurement device (manufactured by KOHZU Corporation, model number: Dyvoce-3000), and a curvature radius R of the blank wafer was measured (refer to FIG. 3B). Next, the curvature radius R of the 4-inch silicon wafer on which the resin layer was formed was measured in the same manner as described above. Then, the curvature radius R was calculated based on the following equation.

Curvature radius R=(curvature radius of wafer on which resin layer is formed−curvature radius of blank wafer)

2) Furthermore, the Young's modulus Es of the silicon wafer, the Poisson's ratio vs of the silicon wafer, the thickness ts of the silicon wafer, the thickness tf of the resin layer, and the curvature radius R were applied to the following equation (3) of Stoney, thereby calculating the stress σ (MPa).

### [Expression 1]

$$σ = \frac{{E}_{s} {t}_{s}^{2}}{6 ( 1 - {v}_{s} ) {Rt}_{f}} \qquad Equation ( 3 )$$

### (7) Amount of Bending

A 4-inch silicon wafer was set in the device Dyvoce-3000 manufactured by KOHZU Corporation, and the amount of bending of the blank wafer was measured.

Next, the amount of bending of the 4-inch silicon wafer on which the resin layer was formed was measured by the same method as described above.

Then, the amount of bending of the sample due to the resin layer was measured based on equation (4).

amount of bending of sample due to resin layer=(amount of bending of wafer on which resin layer is formed−amount of bending of blank wafer) Equation (4):

In the measurement of the amount of bending, the amount of bending at 10201 points of measurement was measured, and the maximum value−the minimum value was adopted.

When the amount of bending was 40 μm or less, it was evaluated as ∘, and when the amount of bending was more than 40 μm, it was evaluated as x.

In a case where the wafer size (8 inches) and the resin layer thickness (10 μm) are assumed for a power semiconductor, when the amount of bending of the wafer before grinding (thickness: 525 μm) was increased up to approximately 40 μm, cracking was more likely to occur after wafer grinding (thickness: 150 μm) due to wafer bending, and thus the evaluation was performed based on the above-described criteria.

Table 1 shows the compositions of the resin layers of the samples 1 to 11, and Table 2 shows the evaluation results. In Table 2, “W” indicates the value of W represented by the equation (1), and “Actual stress” indicates the value calculated in the above “(6) Actual Stress.”

TABLE 1

| | Diamine | | | | | | Acid dianhydride | | | | | | | |
|---|---|---|---|---|---|---|---|---|---|---|---|---|---|---|
| | Mono- | | Mono- | | Mono- | | Mono- | | Mono- | | Mono- | | Mono- | Mono- |
| | mer | Con- | mer | Con- | mer | Con- | mer | Con- | mer | Con- | mer | Con- | mer | mer |
| Sam- | B | tent | A | tent | A | tent | B | tent | B | tent | A | tent | A | B |
| ple | (aro- | (molar | (ali- | (molar | (ali- | (molar | (aro- | (molar | (aro- | (molar | (ali- | (molar | (mol | (mol |
| No. | matic) | ratio) | phatic) | ratio) | phatic) | ratio) | matic) | ratio) | matic) | ratio) | phatic) | ratio) | %) | %) |
| 1 | pBAPP | 0.384 | Dioxa- | 0.576 | | | BPADA | 1 | | | | | 29.4 | 70.6 |
| | | | decane- | | | | | | | | | | | |
| | | | diamine | | | | | | | | | | | |
| 2 | pBAPP | 0.336 | 10DA | 0.624 | | | BPADA | 1 | | | | | 31.8 | 68.2 |
| 3 | pBAPP | 0.566 | 10DA | 0.317 | RT1000 | 0.077 | BPADA | 1 | | | | | 20.1 | 79.9 |
| 4 | pBAPP | 0.97 | | | | | sBPDA | 0.2 | | | BSPA8 | 0.8 | 40.6 | 59.4 |
| 5 | pBAPP | 0.194 | HMDA | 0.776 | | | BPADA | 1 | | | | | 39.4 | 60.6 |
| 6 | pBAPP | 0.588 | Dioxa- | 0.392 | | | BPADA | 1 | | | | | 19.8 | 80.2 |
| | | | decane- | | | | | | | | | | | |
| | | | diamine | | | | | | | | | | | |
| 7 | pBAPP | 0.8 | RT1000 | 0.1 | 1000P | 0.1 | sBPDA | 0.76 | BTDA | 0.2 | | | 10.2 | 89.8 |
| 8 | pBAPP | 0.97 | | | | | BPADA | 1 | | | | | 0 | 100 |
| 9 | APB-N | 0.97 | | | | | sBPDA | 0.7 | BTDA | 0.3 | | | 0 | 100 |
| 10 | pBAPP | 0.97 | | | | | sBPDA | 0.5 | BPADA | 0.5 | | | 0 | 100 |
| 11 | APB-N | 1 | | | | | sBPDA | 0.67 | BTDA | 0.3 | | | 0 | 100 |

TABLE 2

| | | | | | | | Amount of bending | | | | | | | | | | |
|---|---|---|---|---|---|---|---|---|---|---|---|---|---|---|---|---|---|
| | | Variable of equation (1) | | | | | Film | | | | | | | | | | |
| | | | CTE | CTE | Elastic | W | forming | Resin | Board | Amount | | Temporary | Heat resistance | | | | |
| | Heating | Tg | [ppm/ | temp. | modulus | value | temp. | thickness | thickness | of bending | | bending | Td5 | Heat | Solubility | | |
| Sample No. | method | [° C.] | K] | range | [GPa] | [—] | [° C.] | [μm] | [μm] | [μm] | Actual stress | property | [° C.] | resistance | Test result | Solubility | Note |
| 1 | Hot plate | 115 | 75 | 50 to | 2.3 | 21 | 250 | 10 | 525 | 38 | 23 | o | 401 | o | 80° C., 90% or more | o | Present |
| | | | | 100 | | | | | | | | | | | of dissolution rate | | invention |
| | | | | | | | | | | | | | | | in 5 minutes | | |
| 2 | Hot plate | 124 | 70 | 50 to | 2.2 | 22 | 250 | 10 | 525 | 39 | 22 | o | 450 | o | 80° C., 90% or more | o | Present |
| | | | | 100 | | | | | | | | | | | of dissolution rate | | invention |
| | | | | | | | | | | | | | | | in 5 minutes | | |
| 3 | Hot plate | 115 | 67 | 50 to | 2.5 | 23 | 250 | 10 | 525 | 37 | 22 | o | 376 | o | 180° C., 90% or more | o | Present |
| | | | | 100 | | | | | | | | | | | of dissolution rate | | invention |
| | | | | | | | | | | | | | | | in 5 minutes | | |
| 4 | Oven | 145 | 80 | 50 to | 1.7 | 22 | 180 | 11 | 525 | 36 | 21 | o | 461 | o | 80° C., 90% or more | o | Present |
| | | | | 120 | | | | | | | | | | | of dissolution rate | | invention |
| | | | | | | | | | | | | | | | in 3 minutes | | |
| 5 | Oven | 137 | 70 | 50 to | 2.2 | 24 | 180 | 9 | 525 | 31 | 23 | o | 458 | o | 80° C., 90% or more | o | Present |
| | | | | 120 | | | | | | | | | | | of dissolution rate | | invention |
| | | | | | | | | | | | | | | | in 5 minutes | | |
| 6 | Oven | 140 | 63 | 50 to | 2.3 | 25 | 180 | 11 | 525 | 38 | 24 | o | 429 | o | 80° C., 90% or more | o | Present |
| | | | | 120 | | | | | | | | | | | of dissolution rate | | invention |
| | | | | | | | | | | | | | | | in 5 minutes | | |
| 7 | Oven | 137 | 136 | 50 to | 1.7 | 18 | 180 | 10 | 525 | 29 | 18 | o | 353 | Δ | 80° C., | Δ | Present |
| | | | | 120 | | | | | | | | | | | 66% of | | invention |
| | | | | | | | | | | | | | | | dissolution rate in | | |
| | | | | | | | | | | | | | | | 4 to 5 minutes | | |
| 8 | Hot plate | 192 | 52 | 50 to | 2.3 | 33 | 270 | 10 | 525 | 41 | 29 | x | 490 | o | 80° C., | o | Comparison |
| | | | | 150 | | | | | | | | | | | 90% or more | | |
| | | | | | | | | | | | | | | | of dissolution rate | | |
| | | | | | | | | | | | | | | | in 5 minutes | | |
| 9 | Oven | 191 | 49 | 50 to | 3.2 | 38 | 250 | 11 | 525 | 52 | 34 | x | 515 | o | 80° C., | × | Comparison |
| | | | | 150 | | | | | | | | | | | 99% of | | |
| | | | | | | | | | | | | | | | dissolution rate in | | |
| | | | | | | | | | | | | | | | 20 minutes | | |
| 10 | Oven | 209 | 62 | 50 to | 2.2 | 35 | 250 | 9 | 525 | 45 | 35 | x | 499 | o | 80° C., | o | Comparison |
| | | | | 150 | | | | | | | | | | | 90% or more | | |
| | | | | | | | | | | | | | | | of dissolution rate | | |
| | | | | | | | | | | | | | | | in 5 minutes | | |
| 11 | Oven | 187 | 52 | 50 to | 3.2 | 37 | 250 | 9 | 525 | 50 | 40 | x | 557 | o | 80° C., 99% of | x | Comparison |
| | | | | 150 | | | | | | | | | | | dissolution rate in | | |
| | | | | | | | | | | | | | | | 20 minutes | | |

As shown in Table 2, it was found that the samples 8 to 11 having a resin layer that does not satisfy the relationship of the equation (1) had a large amount of bending. In addition, the solubility also tends to be low.

On the other hand, it was found that the samples 1 to 7 having a resin layer satisfying the relationship of the equation (1) had a small amount of bending and good solubility.

In particular, it was found that the larger the content proportion of the monomer (A) was, the smaller the amount of bending of the wafer was, and the higher the solubility was (particularly, the comparison between the samples 1 to 6 and 7).

In addition, it was found that, by using an aliphatic diamine having a long aliphatic chain, the amount of bending of the sample was further reduced (the comparison between the samples 2 and 3).

This application is entitled to and claims the benefits of Japanese Patent Application No. 2023-61636 filed on Apr. 5, 2023, the disclosure of which including the specification and drawings is incorporated herein by reference in its entirety.

### INDUSTRIAL APPLICABILITY

In the producing step of a semiconductor device according to the embodiment of the present invention, it is possible to provide a method for producing a semiconductor device capable of reducing bending of a semiconductor wafer on which a resin layer is formed.

### REFERENCE SIGNS LIST

10 Board
10′ Patterned board
20 Resin layer
30 Support board
40 Photoresist
40′ Resist pattern
50 Laminate

1. A method for producing a semiconductor device, the method comprising:
forming, on a board, a resin layer that includes a polyimide resin;
adhering a support board on the resin layer;
grinding a surface of the board until a thickness of the board becomes 150 μm or less, the board being a board to which the support board is adhered, the surface being located opposite to the resin layer; and
peeling off the support board,
wherein
the resin layer satisfies equation (1) below:
$$W = - 0.042 * X + 5.219 * Y + 0.144 * Z - 4.434 \leq 31 \qquad equation ( 1 )$$
wherein in the equation (1),
X represents a linear thermal expansion coefficient (CTE) (ppm/K) of the resin layer,
Y represents a tensile modulus (GPa) of the resin layer at 23° C., and
Z represents a glass transition temperature (C) of the resin layer,
the polyimide resin includes a polycondensation unit of a tetracarboxylic acid dianhydride and a diamine, and
a monomer composed of the tetracarboxylic acid dianhydride and the diamine includes
a monomer (A) having an aliphatic chain, the monomer (A) including at least one of a tetracarboxylic acid dianhydride represented by formula (A1), a diamine represented by formula (A2), and a diamine represented by formula (A3), and
a monomer (B) having an aromatic ring, the monomer (B) not corresponding to any of the tetracarboxylic acid dianhydride represented by the formula (A1), the diamine represented by the formula (A2), and the diamine represented by the formula (A3): 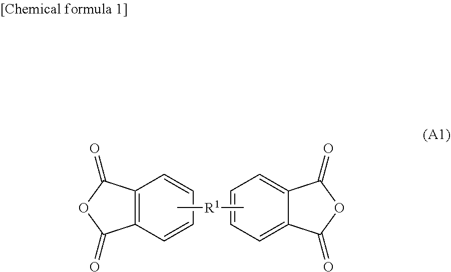
wherein R¹ in the formula (A1) represents an aliphatic chain having a main chain including at least one atom of C, N, and O, and a total number of atoms constituting the main chain is 4 to 20, and 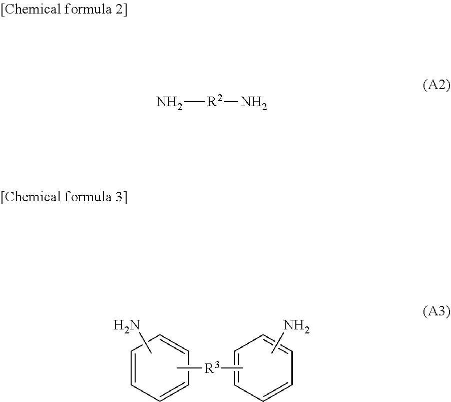
wherein R² in the formula (A2) and R³ in the formula (A3) each represent an aliphatic chain having a main chain including at least one atom of C, N, and O, and a total number of atoms constituting the main chain is 3 to 500.

2. The method according to claim 1, wherein
the CTE of the resin layer is 40 ppm/K or more.

3. The method according to claim 1, wherein
the tensile modulus of the resin layer is 0.5 to 30 GPa.

4. The method according to claim 1, wherein
the glass transition temperature Tg of the resin layer is 250° C. or lower.

5. The method according to claim 1, wherein
a thickness of the resin layer is 10 μm or more.

6. The method according to claim 1, wherein
the monomer includes 7 to 60 mol % of the monomer (A) and 40 to 93 mol % of the monomer (B) based on a total amount of the monomer.

7. The method according to claim 1, wherein
the monomer (B) includes an aromatic tetracarboxylic acid dianhydride represented by formula (B1): 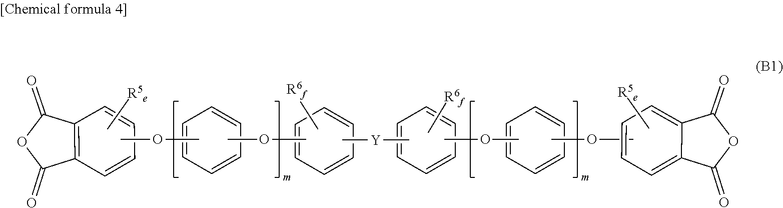
wherein in the formula (B1),
Y represents a divalent group selected from the group consisting of an oxygen atom, a methylene group, and —CR^{a}R^{b} wherein R^{a} and R^{b} each represent a substituted or unsubstituted alkyl group having 1 to 3 carbon atoms,
each m represents an integer of 0 or 1,
R⁵ and R⁶ each represent a substituted or unsubstituted alkyl group having 1 to 3 carbon atoms or an alkoxy group having 1 to 3 carbon atoms, and
e and f each represent an integer of 0 to 3.

8. The method according to claim 1, wherein
the monomer (B) includes an aromatic diamine represented by formula (B2): 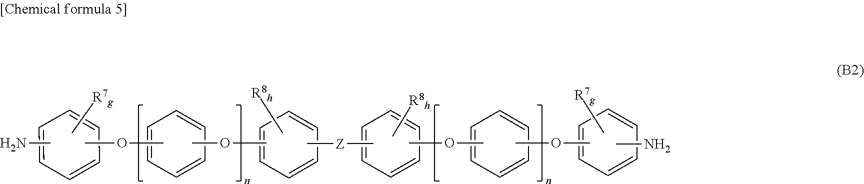
wherein in the formula (B2),
Z represents a divalent group selected from the group consisting of an oxygen atom, a methylene group, and —CR^{c}R^{d} wherein R^{c} and R^{d} each represent a substituted or unsubstituted alkyl group having 1 to 3 carbon atoms,
each n represents an integer of 0 or 1,
R⁷ and R⁸ each represent a substituted or unsubstituted alkyl group having 1 to 3 carbon atoms or an alkoxy group having 1 to 3 carbon atoms, and
g and h each represent an integer of 0 to 3.

9. The method according to claim 1, wherein
the monomer (A) includes a short-chain diamine α in which the total number of atoms constituting the main chain in the formula (A2) or (A3) is 5 to 20.

10. The method according to claim 9, wherein
the monomer (A) further includes a long-chain diamine β in which the total number of atoms constituting the main chain in the formula (A2) or (A3) is 35 to 500.

11. The method according to claim 1, wherein
in the forming the resin layer, when the glass transition temperature of the resin layer is denoted by Tg,
the resin layer is formed by applying a resin composition including the polyimide resin or a precursor of the polyimide resin and then heating the resin composition at a temperature of (Tg+150° C.) or lower.

12. The method according to claim 1, wherein
the board includes silicon or silicon carbide.

13. A laminate for a semiconductor device, the laminate comprising:
a board having a thickness of 150 μm or less; and
a resin layer disposed on the board and including a polyimide resin,
wherein
the resin layer satisfies equation (1) below:
$$W = - 0.042 * X + 5.219 * Y + 0.144 * Z - 4.434 \leq 31 \qquad equation ( 1 )$$
wherein in the equation (1),
X represents a linear thermal expansion coefficient (CTE) (ppm/K) of the resin layer,
Y represents a tensile modulus (GPa) of the resin layer at 23° C., and
Z represents a glass transition temperature (° C.) of the resin layer,
the polyimide resin includes a polycondensation unit of a tetracarboxylic acid dianhydride and a diamine, and
a monomer composed of the tetracarboxylic acid dianhydride and the diamine includes
a monomer (A) having an aliphatic chain, the monomer (A) including at least one of a tetracarboxylic acid dianhydride represented by formula (A1), a diamine represented by formula (A2), and a diamine represented by formula (A3), and
a monomer (B) having an aromatic ring, the monomer (B) not corresponding to any of the tetracarboxylic acid dianhydride represented by the formula (A1), the diamine represented by the formula (A2), and the diamine represented by the formula (A3): 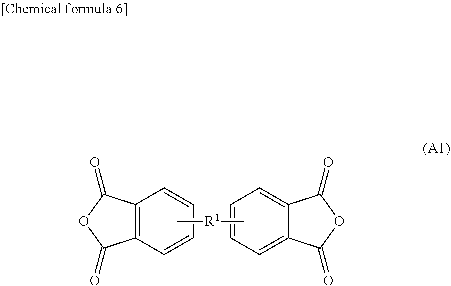
wherein R¹ in the formula (A1) represents an aliphatic chain having a main chain including at least one atom of C, N, and O, and a total number of atoms constituting the main chain is 4 to 20, and 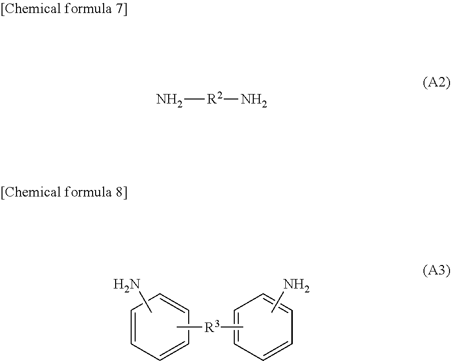
wherein R² in the formula (A2) and R³ in the formula (A3) each represent an aliphatic chain having a main chain including at least one atom of C, N, and O, and a total number of atoms constituting the main chain is 3 to 500.

14. The laminate according to claim 13, wherein
the CTE of the resin layer is 40 ppm/K or more.

15. The laminate according to claim 13, wherein
the tensile modulus of the resin layer is 0.5 to 30 GPa.

16. The laminate according to claim 13, wherein
the glass transition temperature Tg of the resin layer is 250° C. or lower.

17. The laminate according to claim 13, wherein
the monomer includes 7 to 60 mol % of the monomer (A) and 40 to 93 mol % of the monomer (B) based on a total amount of the monomer.

18. The laminate according to claim 13, wherein
a thickness of the resin layer is 10 μm or more.

19. The laminate according to claim 13, wherein
the board includes silicon or silicon carbide.
